(19) United States
(12) Patent Application Publication
(10) Pub. No.: US 2023/0200037 A1
(43) Pub. Date: Jun. 22, 2023

(54) BOARD MANUFACTURING SYSTEM, AUTONOMOUS MOBILE CART, AND BOARD MANUFACTURING METHOD

(71) Applicant: YAMAHA HATSUDOKI KABUSHIKI KAISHA, Iwata-shi, Shizuoka (JP)

(72) Inventors: Yasuhiro KANEKO, Iwata-shi, Shizuoka (JP); Yusetsu KOBAYASHI, Iwata-shi, Shizuoka (JP)

(73) Assignee: YAMAHA HATSUDOKI KABUSHIKI KAISHA, Iwata-shi, Shizuoka (JP)

(21) Appl. No.: 17/999,171

(22) PCT Filed: May 26, 2020
(86) PCT No.: PCT/JP2020/020683

§ 371 Date: Nov. 17, 2022

(51) Int. Cl. H05K 13/04; B25J 9/00; B25J 9/16

(52) U.S. Cl. CPC H05K 13/0495; B25J 9/0096; B25J 9/162

(57) ABSTRACT

A board manufacturing system includes an autonomous mobile cart configured to transport an object used in board work devices of a mounting line, a robot arm provided on the autonomous mobile cart and configured to transport the object used in the board work devices to the board work devices, and a controller provided in the autonomous mobile cart and configured or programmed to control driving of the robot arm. The controller is configured or programmed to control the driving of the robot arm such that the robot arm transports the object used in the board work devices into and out of the board work devices within a movable range of a working unit in the board work devices in a plan view.

### CROSS-REFERENCE TO RELATED APPLICATION

This application is a National Stage of International Patent Application No. PCT/JP2020/020683, filed May 26, 2020, the entire content of which is incorporated herein by reference.

### BACKGROUND

### Technical Field

The present disclosure relates to a board manufacturing system, an autonomous mobile cart, and a board manufacturing method.

### Background Art

Conventionally, a board manufacturing system is known. Such a board manufacturing system is disclosed in Japanese Patent Laid-Open No. 2017-216379, for example.

Japanese Patent Laid-Open No. 2017-216379 discloses a board manufacturing system including a component mounting device that mounts components on a board and a mobile component supply device that replenishes the component mounting device with components to be mounted by the component mounting device. In the board manufacturing system disclosed in Japanese Patent Laid-Open No. 2017-216379, the mobile component supply device supplies a reel on which a tape that holds components is wound to a tape feeder arranged in the component mounting device to supply the components held on the tape.

### SUMMARY

In the board manufacturing apparatus disclosed in Japanese Patent Laid-Open No. 2017-216379, the reel on which the tape that holds components is wound is supplied to the tape feeder arranged in the component mounting device by the mobile component supply device, and thus it is not necessary for an operator to replenish the component mounting device with components. However, it is necessary for the operator to replenish the component mounting device and another board work device with objects (such as nozzles or backup pins) used in the component mounting device and another board work device, and thus it is difficult to reduce the work burden on the operator.

The present disclosure provided a board manufacturing system, an autonomous mobile cart, and a board manufacturing method each capable of reducing the work burden on an operator when an object used in a board work device is transported into and out of the board work device.

A board manufacturing system according to a first aspect of the present disclosure includes a mounting line including a plurality of board work devices. The plurality of board work devices includes a component mounting device configured to mount a component on a board, an autonomous mobile cart configured to transport an object used in the board work devices of the mounting line, a robot arm provided on the autonomous mobile cart and configured to transport the object used in the board work devices to the board work devices, and a controller provided in the autonomous mobile cart or the robot arm and configured or programmed to control driving of the robot arm. The board work devices include a working unit configured to work on the board, the controller is configured or programmed to control the driving of the robot arm such that the robot arm transports the object used in the board work devices into and out of the board work devices within a movable range of the working unit in the board work devices in a plan view, and the controller is configured or programmed to control the driving of the robot arm such that the robot arm delivers and receives the object used in the board work devices to and from the working unit in the board work devices.

In the board manufacturing system according to the first aspect of the present disclosure, as described above, the controller is configured or programmed to control the driving of the robot arm such that the robot arm transports the object used in the board work devices into and out of the board work devices within the movable range of the working unit in the board work devices in the plan view. Accordingly, the robot arm can transport the object used in the board work devices (such as a nozzle, a backup pin, a waste box, or a calibration jig) into and out of the board work devices, and thus an operator does not need to transport the object into and out of the board work devices. Consequently, it is possible to reduce the work burden on the operator when the object used in the board work devices is transported into and out of the board work devices. Moreover, unlike a case in which the operator transports the object into and out of the board work devices, it is not necessary to stop the operations of the board work devices completely. Thus, it is possible to significantly reduce or prevent a decrease in the efficiency (productivity) of board manufacturing by the board work devices. Furthermore, the object can be transported into and out of the board work devices by the robot arm when necessary in the board work devices, and thus it is not necessary to provide a storage space for storing the object in the board work devices in case the object used in the board work devices is required. Thus, the board work devices can be downsized.

In the aforementioned board manufacturing system according to the first aspect, the working unit that works on the board can be used to deliver and receive the object to and from the robot arm, and thus it is not necessary to provide a dedicated member for delivering and receiving the object to and from the robot arm. Thus, it is possible to significantly reduce or prevent an increase in the number of components of the board work devices and to significantly reduce or prevent the complexity of the device structures.

In the aforementioned board manufacturing system according to the first aspect, the board work devices are preferably configured to recognize the object transported into the movable range of the working unit and receive the object from the robot arm with the working unit based on a recognition result. Accordingly, the position of the transported object can be accurately recognized, and the transported object can be reliably received by the working unit.

In the aforementioned board manufacturing system in which the working unit receives the object from the robot arm based on the recognition result of the transported object, the board work devices are preferably configured to recognize a type of the object transported into the movable range of the working unit. Accordingly, the object can be received by the working unit in a suitable manner according to the type of transported object.

In the aforementioned board manufacturing system in which the working unit receives the object from the robot arm based on the recognition result of the transported object, the board work devices preferably include a camera configured to recognize the board to be worked on, and are preferably configured to image the object transported into the movable range of the working unit with the camera and recognize the object based on an imaging result. Accordingly, the camera that recognizes the board can be used to image and recognize the transported object, and thus it is not necessary to provide a dedicated member for recognizing the transported object. Thus, it is possible to significantly reduce or prevent an increase in the number of components of the board work devices and to significantly reduce or prevent the complexity of the device structures.

In the aforementioned board manufacturing system according to the first aspect, the controller is preferably configured or programmed to control the driving of the robot arm such that the robot arm delivers and receives the object used in the component mounting device to and from a mounting head corresponding to the working unit of the component mounting device. Accordingly, the robot arm can deliver and receive the object used in the component mounting device to and from the mounting head of the component mounting device, and thus it is possible to reduce the work burden on the operator when the object used in the component mounting device is transported into and out of the component mounting device.

The aforementioned board manufacturing system according to the first aspect preferably further includes a server configured to communicate with the autonomous mobile cart and the plurality of board work devices, and the server is preferably configured to receive information on a demanded object from the board work devices and transmit, to the corresponding autonomous mobile cart, an instruction to transport the object to the board work devices. Accordingly, the server can collectively manage the objects to be transported to the plurality of board work devices, and thus the objects can be efficiently transported to the plurality of board work devices.

In the aforementioned board manufacturing system according to the first aspect, the controller is preferably configured or programmed to recognize a position of an opening through which the robot arm is inserted into the board work devices and move the autonomous mobile cart to the position of the opening. Accordingly, the robot arm can be easily inserted into the openings of the board work devices and easily transport the object into and out of the board work devices.

In the aforementioned board manufacturing system according to the first aspect, the controller is preferably configured or programmed to control the driving of the robot arm such that the robot arm transports the object used in the board work devices to positions designated by the board work devices or preset positions of the board work devices. Accordingly, the robot arm can transport the object used in the board work devices to the predetermined positions, and thus the transported object can be easily delivered and received by predetermined operations of the board work devices.

In the aforementioned board manufacturing system according to the first aspect, the board work devices are preferably configured to retract the working unit such that the working unit does not interfere with the robot arm when the robot arm is inserted. Accordingly, it is possible to significantly reduce or prevent interference between the robot arm and the working units of the board work devices while the robot arm is transporting the object, and thus it is possible to significantly reduce or prevent fall of the object from the robot arm.

In the aforementioned board manufacturing system according to the first aspect, the object used in the board work devices preferably includes at least one of a backup pin configured to support the board, a nozzle configured to suction the component, a waste box in which the component is discarded, or a calibration jig used to calibrate the board work devices. Accordingly, it is possible to reduce the work burden on the operator when the backup pin, the nozzle, the waste box, and the calibration jig are transported to the board work devices.

An autonomous mobile cart according to a second aspect of the present disclosure includes an autonomous mobile cart main body configured to transport an object used in board work devices of a mounting line including a plurality of the board work devices, the plurality of board work devices including a component mounting device configured to mount a component on a board, a robot arm provided on the autonomous mobile cart and configured to transport the object used in the board work devices to the board work devices, and a controller provided in the autonomous mobile cart or the robot arm and configured or programmed to control driving of the robot arm. The controller is configured or programmed to control the driving of the robot arm such that the robot arm transports the object used in the board work devices into and out of the board work devices within a movable range of a working unit configured to work on the board in the board work devices in a plan view, and the controller is configured or programmed to control the driving of the robot arm such that the robot arm delivers and receives the object used in the board work devices to and from the working unit in the board work devices.

In the autonomous mobile cart according to the second aspect of the present disclosure, as described above, the controller is configured or programmed to control the driving of the robot arm such that the robot arm transports the object used in the board work devices into and out of the board work devices within the movable range of the working unit in the board work devices in the plan view. Accordingly, the robot arm can transport the object used in the board work devices into and out of the board work devices, and thus an operator does not need to transport the object into and out of the board work devices. Consequently, it is possible to provide the autonomous mobile cart capable of reducing the work burden on the operator when the object used in the board work devices is transported into and out of the board work devices. Moreover, unlike a case in which the operator transports the object into and out of the board work devices, it is not necessary to stop the operations of the board work devices completely. Thus, it is possible to significantly reduce or prevent a decrease in the efficiency (productivity) of board manufacturing by the board work devices. Furthermore, the object can be transported into and out of the board work devices by the robot arm when necessary in the board work devices, and thus it is not necessary to provide a storage space for storing the object in the board work devices in case the object used in the board work devices is required. Thus, the board work devices can be downsized.

A board manufacturing method in a mounting line including a plurality of board work devices, the plurality of board work devices including a component mounting device configured to mount a component on a board, according to a third aspect of the present disclosure includes transporting an object used in the board work devices of the mounting line by an autonomous mobile cart, driving a robot arm such that the robot arm transports the object used in the board work devices into and out of the board work devices within a movable range of a working unit configured to work on the board in the board work devices in a plan view, and driving the robot arm such that the robot arm delivers and receives the object used in the board work devices to and from the working unit in the board work devices.

As described above, the board manufacturing method according to the third aspect of the present disclosure includes driving the robot arm such that the robot arm transports the object used in the board work devices into and out of the board work devices within the movable range of the working unit configured to work on the board in the board work devices in the plan view. Accordingly, the robot arm can transport the object used in the board work devices into and out of the board work devices, and thus an operator does not need to transport the object into and out of the board work devices. Consequently, it is possible to provide the board manufacturing method capable of reducing the work burden on the operator when the object used in the board work devices is transported into and out of the board work devices. Moreover, unlike a case in which the operator transports the object into and out of the board work devices, it is not necessary to stop the operations of the board work devices completely. Thus, it is possible to significantly reduce or prevent a decrease in the efficiency (productivity) of board manufacturing by the board work devices. Furthermore, the object can be transported into and out of the board work devices by the robot arm when necessary in the board work devices, and thus it is not necessary to provide a storage space for storing the object in the board work devices in case the object used in the board work devices is required. Thus, the board work devices can be downsized.

According to the present disclosure, as described above, it is possible to reduce the work burden on the operator when the object used in the board work device is transported into and out of the board work device.

### BRIEF DESCRIPTION OF THE DRAWINGS

FIG. 1 is a block diagram schematically showing a board manufacturing system according to an embodiment of the present disclosure;

FIG. 2 is a block diagram schematically showing an autonomous mobile cart according to the embodiment of the present disclosure;

FIG. 3 is a perspective view showing the autonomous mobile cart according to the embodiment of the present disclosure;

FIG. 4 is a plan view showing the structure of a component mounting device according to the embodiment of the present disclosure;

FIG. 5 is a front view showing the structure of the component mounting device according to the embodiment of the present disclosure;

FIG. 6 is a perspective view showing a robot arm according to the embodiment of the present disclosure;

FIG. 7 is a front view showing a carry-in port of the component mounting device according to the embodiment of the present disclosure;

FIG. 8 is a plan view showing a tool transported by the robot arm according to the embodiment of the present disclosure;

FIG. 9 is a diagram showing an example of information on the autonomous mobile cart managed by a server according to the embodiment of the present disclosure;

FIG. 10 is a diagram showing an example of information on a toolbox of the autonomous mobile cart managed by the server according to the embodiment of the present disclosure;

FIG. 11 is a diagram showing an example of information on a production plan of the component mounting device managed by the server according to the embodiment of the present disclosure;

FIG. 12 is a diagram showing an example of position information of the component mounting device managed by the server according to the embodiment of the present disclosure;

FIG. 13 is a perspective view showing a hand holder of the robot arm according to the embodiment of the present disclosure;

FIGS. 14A-14E are diagrams for illustrating holding of a nozzle stocker by the robot arm according to the embodiment of the present disclosure;

FIG. 15 is a diagram for illustrating holding of a backup pin stocker by the robot arm according to the embodiment of the present disclosure;

FIG. 16 is a side view showing a state in which movement of the robot arm is restricted according to the embodiment of the present disclosure;

FIG. 17 is a perspective view for illustrating connection of the autonomous mobile cart to the component mounting device according to the embodiment of the present disclosure;

FIG. 18 is a plan view for illustrating connection of the autonomous mobile cart to the component mounting device according to the embodiment of the present disclosure;

FIGS. 19A-19C are side views for illustrating insertion of the robot arm into the carry-in port of the component mounting device according to the embodiment of the present disclosure;

FIGS. 20A-20C are side views for illustrating insertion of the robot arm into an opening of the component mounting device created by removing a component supply cart according to the embodiment of the present disclosure;

FIG. 21 is a front view showing a waste box of the component mounting device according to the embodiment of the present disclosure;

FIG. 22 is a front view for illustrating installation of a calibration jig for the component mounting device according to the embodiment of the present disclosure;

FIG. 23 is a first flowchart for illustrating a tool supply process according to the embodiment of the present disclosure; and

FIG. 24 is a second flowchart for illustrating a tool supply process according to the embodiment of the present disclosure;

### DETAILED DESCRIPTION

An embodiment embodying the present disclosure is hereinafter described on the basis of the drawings.

Structure of Board Manufacturing System

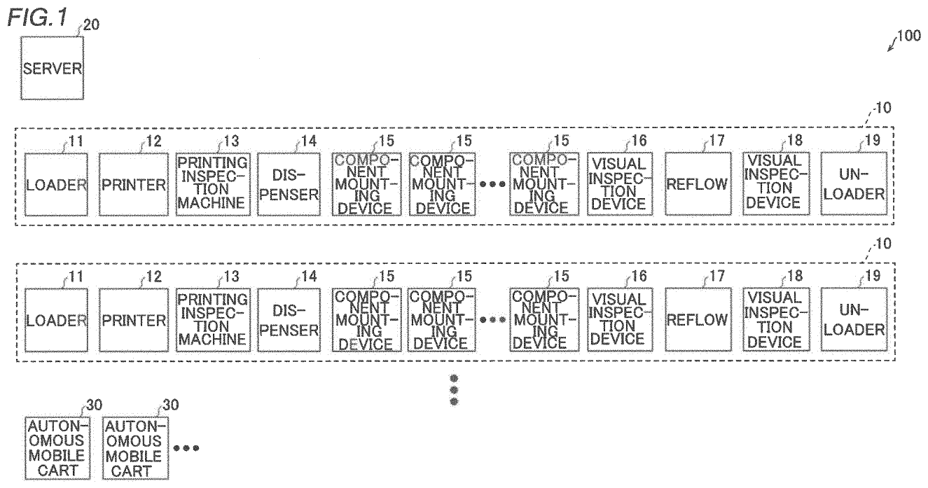

The structure of a board manufacturing system 100 according to the embodiment of the present disclosure is now described with reference to FIG. 1.

The board manufacturing system 100 according to this embodiment mounts components E on a board S to manufacture the board S on which the components E are mounted. As shown in FIG. 1, the board manufacturing system 100 includes mounting lines 10, a server 20, and a plurality of autonomous mobile carts 30.

A plurality of mounting lines 10 are provided. The mounting lines 10 each include a loader 11, a printer 12, a printing inspection machine 13, a dispenser device 14, a plurality of component mounting devices 15, a visual inspection device 16, a reflow device 17, a visual inspection device 18, and an unloader 19. In the mounting line 10, the board S is conveyed from the upstream side (left side) to the downstream side (right side) along the production line. The loader 11, the printer 12, the printing inspection machine 13, the dispenser device 14, the component mounting devices 15, the visual inspection device 16, the reflow device 17, the visual inspection device 18, and the unloader 19 are examples of a “board work device” in the claims.

Structure of Mounting Line

The structure of each device of the mounting line 10 is now described.

The loader 11 has a role of holding the board (wiring board) S before the components E are mounted and loading the board S to the mounting line 10. The components include small pieces of electronic components such as LSIs, ICs, transistors, capacitors, and resistors.

The printer 12 is a screen printer and has a function of applying cream solder on a mounting surface of the board.

The printing inspection machine 13 has a function of inspecting the state of the cream solder printed by the printer 12.

The dispenser device 14 has a function of applying cream solder, an adhesive, etc. to the board S.

The component mounting devices 15 have a function of mounting the components E at predetermined mounting positions on the board on which the cream solder has been printed. A plurality of component mounting devices 15 are arranged along the conveyance direction of the board.

The visual inspection device 16 is provided downstream of the plurality of component mounting devices 15. The visual inspection device 16 has a function of inspecting the appearance of the board S on which the components E have been mounted by the component mounting devices 15.

The reflow device 17 has a function of melting the solder by performing a heat treatment and joining the components E to electrode portions of the board S. The reflow device 17 is configured to perform the heat treatment while conveying the board on the lane.

The visual inspection device 18 is provided downstream of the reflow device 17. The visual inspection device 18 has a function of inspecting the appearance of the board heat-treated by the reflow device 17.

The unloader 19 has a role of discharging the board S on which the components E have been mounted from the mounting line 10.

A passage is provided between the plurality of mounting lines 10 for an operator and the autonomous mobile carts 30 to pass therethrough and perform an operation.

The server 20 manages information on the mounting lines 10. The server 20 manages data related to the type and number of boards manufactured by the mounting lines 10, the type of components E to be mounted, the inventory quantity of components E, and mounting. The server 20 can communicate with each device (the loader 11, the printer 12, the printing inspection machine 13, the dispenser device 14, the component mounting devices 15, the visual inspection device 16, the reflow device 17, the visual inspection device 18, and the unloader 19) of the mounting line 10. Furthermore, the server 20 can communicate with the autonomous mobile carts 30. That is, the server 20 transmits commands to the autonomous mobile carts 30. The server 20 receives information such as video from the autonomous mobile carts 30. The server 20 includes a computer including a controller such as a CPU, a storage, and a communicator.

Structure of Autonomous Mobile Cart

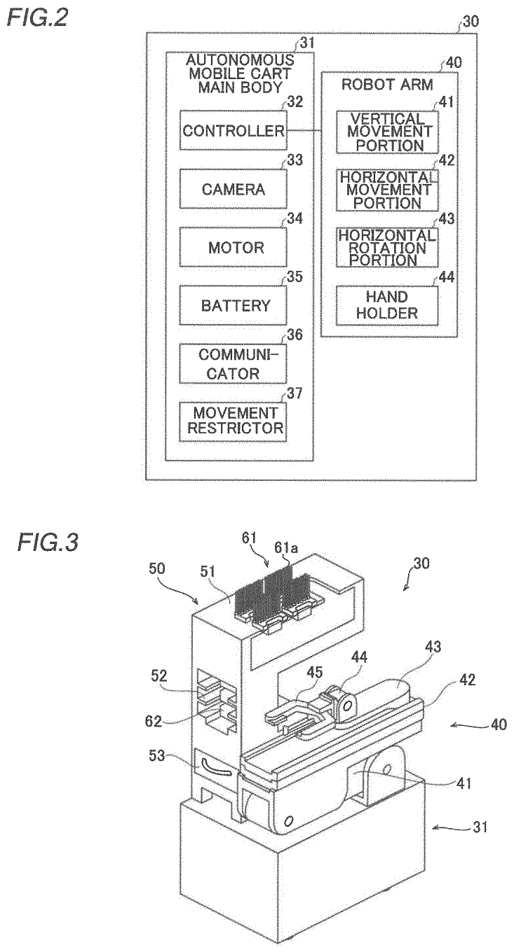

The structure of the autonomous mobile carts 30 according to the embodiment of the present disclosure is described with reference to FIGS. 2 and 3.

The autonomous mobile carts 30 each autonomously travel, and transport objects used in each device (the loader 11, the printer 12, the printing inspection machine 13, the dispenser device 14, the plurality of component mounting devices 15, the visual inspection device 16, the reflow device 17, the visual inspection device 18, and the unloader 19) of the mounting line 10. Specifically, the autonomous mobile cart 30 transports the components E to be mounted by the component mounting devices 15 and replenishes the component mounting devices 15 with the components E. The autonomous mobile cart 30 transports a tool 60 used in equipment on the mounting line 10 such as a nozzle 62a for mounting the components E or a backup pin 61a. Furthermore, the autonomous mobile cart 30 can tow and transport a component supply cart 153b mounted on the component mounting device 15. The component supply cart 153b can hold a plurality of component supply devices (tape feeders 153a).

As shown in FIG. 2, the autonomous mobile cart 30 includes an autonomous mobile cart main body 31 and a robot arm 40. The autonomous mobile cart main body 31 includes a controller 32, a camera 33, a motor 34, a battery 35, a communicator 36, and a movement restrictor 37. The robot arm 40 includes a vertical movement portion 41, a horizontal movement portion 42, a horizontal rotation portion 43, and a hand holder 44. The autonomous mobile cart main body 31 is an example of an “autonomous mobile cart” in the claims.

The controller 32 is provided in the autonomous mobile cart main body 31. The controller 32 controls each portion of the autonomous mobile cart 30. The controller 32 includes a CPU (central processing unit) and a memory. The controller 32 controls the motor 34 to control autonomous traveling of the autonomous mobile cart main body 31. The controller 32 controls the autonomous mobile cart main body 31 to autonomously travel toward a destination based on stored or acquired position information. For example, the controller 32 acquires the position information based on a tape arranged on the floor surface. Alternatively, the controller 32 acquires and stores the position information based on the arrangement data of the mounting line 10. Alternatively, the controller 32 acquires the position information based on a signal received from a specific position in a traveling region.

The controller 32 controls driving of the robot arm 40.

The camera 33 images the surrounding state of the autonomous mobile cart 30. The camera 33 is provided on at least one of the autonomous mobile cart main body 31 or the robot arm 40. The camera 33 is used to detect the position of the component mounting device 15 to which the objects are to be transported and the position of an opening of the component mounting device 15 to which the objects are to be transported. That is, the camera 33 images the periphery of the opening, and the controller 32 detects the position of the opening based on the imaging result. Furthermore, the camera 33 captures an image in order to obtain information necessary for autonomous traveling of the autonomous mobile cart main body 31.

The motor 34 drives wheels for the autonomous mobile cart main body 31 to autonomously travel. The motor 34 drives the wheels to move the autonomous mobile cart main body 31 forward and rearward and turn the autonomous mobile cart main body 31.

The battery 35 supplies electric power to each portion of the autonomous mobile cart 30. The battery 35 includes a rechargeable battery. The autonomous mobile cart main body 31 autonomously travels by the electric power of the battery 35. Furthermore, the robot arm 40 is driven by the electric power of the battery 35. When the electric power of the battery 35 becomes low, the autonomous mobile cart main body 31 autonomously travels to a charging station to charge the battery 35.

The movement restrictor 37 fixes the robot arm 40 to the autonomous mobile cart main body 31 such that the robot arm 40 does not move when the autonomous mobile cart main body 31 is traveling.

As shown in FIG. 3, the autonomous mobile cart 30 includes a placement portion 50 on which a plurality of types of objects used in the component mounting device 15 are placed. The placement portion 50 includes a backup pin placement portion 51 on which a backup pin stocker 61 in which a plurality of backup pins 61a supporting the board S are arranged is placed, a nozzle placement portion 52 on which a nozzle stocker 62 in which a plurality of nozzles 62a suctioning the components E are arranged is placed, and a waste storage 53 that stores the waste in a waste box 63.

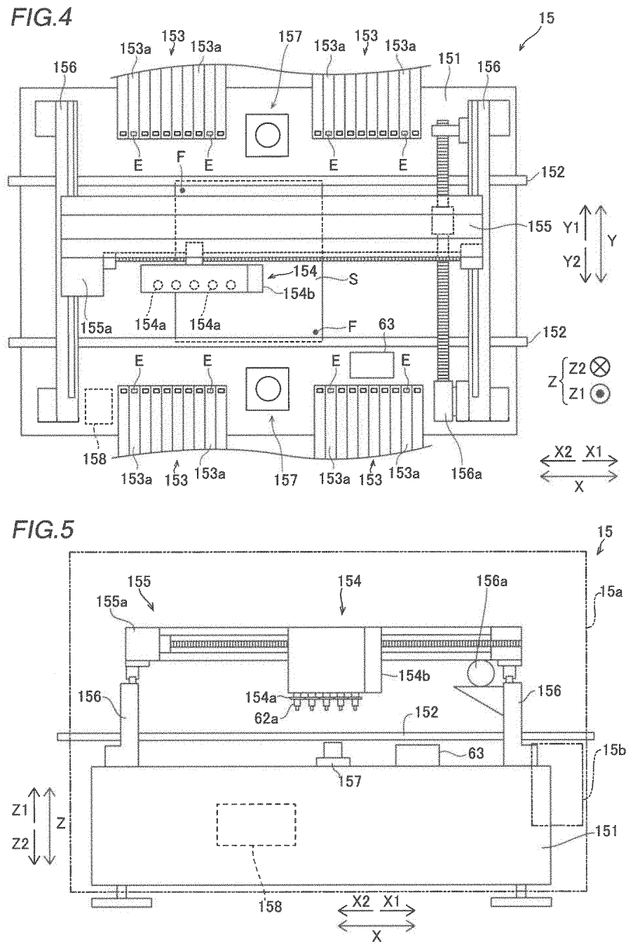

As shown in FIGS. 4 and 5, the component mounting device 15 has a function of mounting the components at the predetermined mounting positions on the board S on which the cream solder has been printed. The component mounting device 15 includes a base 151, a pair of conveyors 152, component supply units 153, a head unit 154, a support 155, a pair of rails 156, and component recognition imagers 157, and a controller 158. Furthermore, as shown in FIG. 5, the component mounting device 15 includes a housing 15a and a carry-in port 15b provided in the housing 15a.

The pair of conveyors 152 are installed on the base 151 and convey the board S in an X direction. Furthermore, the pair of conveyors 152 hold the board S being conveyed in a stopped state at a mounting operation position. A distance between the pair of conveyors 152 in a Y direction can be adjusted according to the dimensions of the board S.

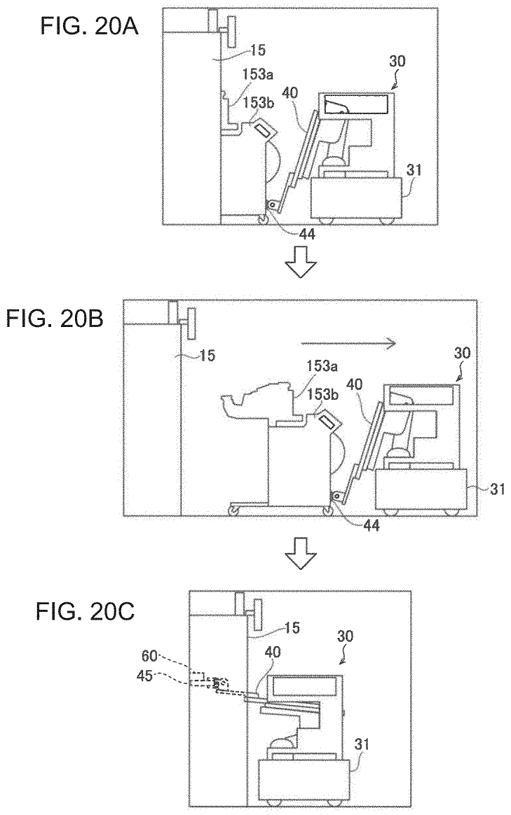

The component supply units 153 are arranged outside (Y1 and Y2 sides) of the pair of conveyors 152. Furthermore, a plurality of tape feeders 153a held on the component supply cart 153b (see FIG. 20) are arranged in the component supply units 153.

The tape feeders 153a hold reels on which tapes that hold a plurality of components E at a predetermined interval are wound. The tape feeders 153a are configured to supply the components E from the tip ends of the tape feeders 153a by rotating the reels to feed the tapes that hold the components E.

The head unit 154 is provided so as to move between an area above the pair of conveyors 152 and areas above the component supply units 153. The head unit 154 includes a plurality of (five) mounting heads 154a having nozzles attached to the lower ends, and a board recognition imager 154b. The mounting heads 154a are examples of a “working unit” in the claims. The board recognition imager 154b is an example of a “camera” in the claims.

The mounting heads 154a are configured to work on the board S. The mounting heads 154a are configured to mount the components E on the board S. Specifically, the mounting heads 154a are configured to be movable up and down (movable in a Z direction), and are configured to suction and hold the components E supplied from the tape feeders 153a by a negative pressure generated at the tip ends of the nozzles 62a by an air pressure generator and to mount the components E at the mounting positions on the board S.

The board recognition imager 154b is configured to image fiducial marks F of the board S in order to recognize the position and orientation of the board S to be worked on. The positions of the fiducial marks F are imaged and recognized such that the mounting positions of the components E on the board S can be accurately acquired. The board recognition imager 154b is configured to image the board S from above (Z1 direction side). Furthermore, the board recognition imager 154b is configured to image an object transported into the component mounting device 15 by the robot arm 40 within a movable range of the mounting heads 154a.

The support 155 includes an X-axis motor 155a. The support 155 is configured to move the head unit 154 in the X direction along the support 155 by driving the X-axis motor 155a. Opposite ends of the support 155 are supported by the pair of rails 156.

The pair of rails 156 are fixed on the base 151. A rail 156 on the X1 side includes a Y-axis motor 156a. The rails 156 are configured to move the support 155 in the Y direction orthogonal to the X direction along the pair of rails 156 by driving the Y-axis motor 156a. The head unit 154 is movable in the X direction along the support 155, and the support 155 is movable in the Y direction along the rails 156 such that the head unit 154 is movable in the X and Y directions.

The component recognition imagers 157 are fixed on the upper surface of the base 151. The component recognition imagers 157 are arranged outside (Y1 and Y2 sides) of the pair of conveyors 152. The component recognition imagers 157 are configured to image the components E suctioned by the nozzles of the mounting heads 154a from below (Z2 direction side) in order to recognize the suction states (suction orientations) of the components E prior to mounting of the components E. Thus, the suction states of the components E suctioned by the nozzles of the mounting heads 154a can be acquired.

The waste box 63 is arranged on the upper surface of the base 151. The waste box 63 is placed on the base 151 such that it can be transported by the robot arm 40.

The controller 158 includes a CPU, and is configured to control the overall operation of the component mounting device 15 such as the board S conveying operation performed by the pair of conveyors 152, the mounting operation performed by the head unit 154, and the imaging operations performed by the component recognition imagers 157 and the board recognition imager 154b. Furthermore, the controller 158 is configured to be able to communicate with the server 20. The controller 158 is configured to receive and transmit information such as production information and component information from and to the server 20.

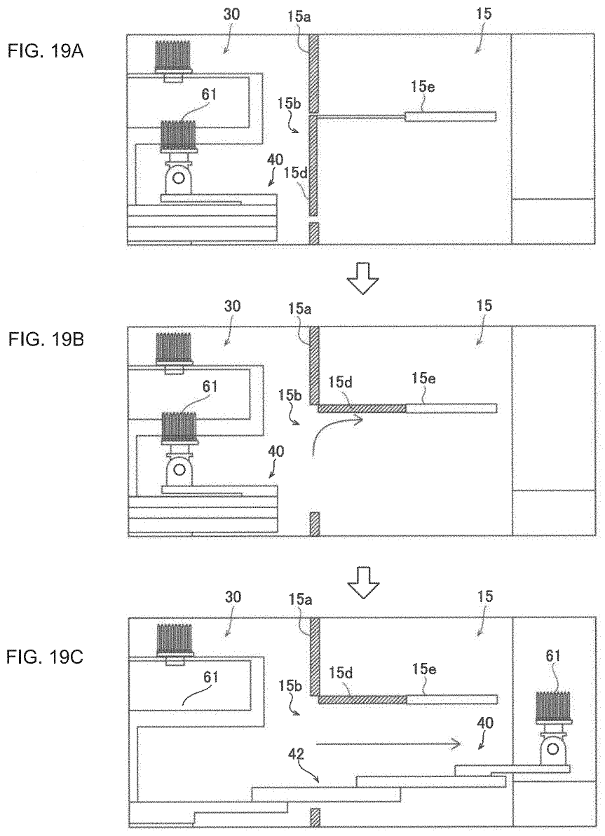

The housing 15a is provided so as to cover the component mounting device 15. The carry-in port 15b includes an opening leading to the inside of the component mounting device 15. The robot arm 40 is inserted into the carry-in port 15b. The carry-in port 15b is covered with a cover 15d (see FIGS. 19A-19C) when the robot arm 40 is not inserted thereinto. When the robot arm 40 is inserted thereinto, the carry-in port 15b is opened by moving the cover 15d.

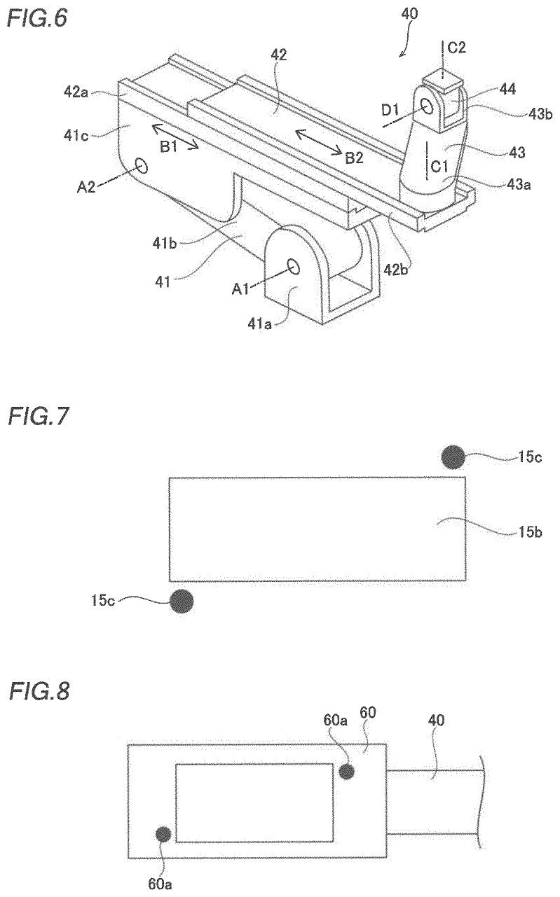

As shown in FIG. 3, the robot arm 40 is provided on the autonomous mobile cart main body 31. The robot arm 40 is configured to transport the objects used in the component mounting device 15 to the component mounting device 15. As shown in FIG. 6, the robot arm 40 includes the vertical movement portion 41 including a rotary shaft that rotates in a vertical direction, a horizontal movement portion 42 that is connected to the vertical movement portion 41 and expands and contracts along a horizontal direction, the horizontal rotation portion 43 that is connected to the horizontal movement portion 42 and rotates in the horizontal direction, and the hand holder 44 connected to the horizontal rotation portion 43 and having a tip end to and from which different types of hands 45 are attachable and detachable. The vertical movement portion 41 includes a base 41a, an arm 41b, and an arm 41c. The horizontal movement portion 42 includes a slider 42a and a slider 42b. The horizontal rotation portion 43 includes an arm 43a and a connecting portion 43b.

The base 41a of the vertical movement portion 41 is fixed to the autonomous mobile cart main body 31. The arm 41b is provided so as to be rotatable about a rotation axis A1 with respect to the base 41a. The arm 41c is provided so as to be rotatable about a rotation axis A2 with respect to the arm 41b.

The slider 42a of the horizontal movement portion 42 is provided so as to be slidable with respect to the arm 41c of the vertical movement portion 41 in a B1 direction (a horizontal direction in a case in which the arms 41b and 41c are not rotating). The slider 42b is provided so as to be slidable with respect to the slider 42a in a B2 direction (a horizontal direction in a case in which the arms 41b and 41c are not rotating).

The arm 43a of the horizontal rotation portion 43 is provided so as to be rotatable about a rotation axis C1 with respect to the slider 42b of the horizontal movement portion 42. The connecting portion 43b is provided so as to be rotatable about a rotation axis C2 with respect to the arm 43a.

The hand holder 44 is provided so as to be rotatable about a rotation axis D1 with respect to the connecting portion 43b of the horizontal rotation portion 43. The hand holder 44 holds the hand 45 (see FIG. 3) at its tip end such that the hand 45 is detachable therefrom. As shown in FIG. 15, the hand holder 44 holds the backup pin stocker 61 such that the backup pin stocker 61 is detachable therefrom. As shown in FIGS. 20A-20C, the hand holder 44 is connectable to the component supply cart 153b.

As shown in FIG. 7, a plurality of marks 15c are provided at the carry-in port 15b. The marks 15c are provided to be imaged and recognized by the camera 33 of the autonomous mobile cart 30. The controller 32 of the autonomous mobile cart 30 acquires the position of the carry-in port 15b based on the imaging results of the marks 15c by the camera 33. Specifically, the controller 32 acquires, from the server 20, information on the component mounting device 15 that requests the tool 60 (the backup pin 61a, the nozzle 62a, or the waste box 63) to be transported. The information to be acquired includes the type of tool 60 requested by the component mounting device 15, planar position information of the component mounting device 15, and three-dimensional position information of the carry-in port 15b of the component mounting device 15. The controller 32 moves the autonomous mobile cart main body 31 based on the planar position information of the component mounting device 15. After moving the autonomous mobile cart main body 31 to the front of the target component mounting device 15, the controller 32 images the periphery of the carry-in port 15b with the camera 33. The controller 32 recognizes the marks 15c provided at the carry-in port 15b from the imaging result, and acquires the position of the carry-in port 15b.

As shown in FIG. 8, a plurality of marks 60a are provided on the tool 60 transported into the component mounting device 15 by the robot arm 40. The marks 60a are provided to be imaged and recognized by the board recognition imager 154b of the component mounting device 15. The controller 158 of the component mounting device 15 acquires the position of the tool 60 transported into the component mounting device 15 based on the imaging result of the marks 60a by the board recognition imager 154b. That is, the controller 158 images the object transported in the movable range of the mounting heads 154a with the board recognition imager 154b and recognizes the object based on the imaging result. Specifically, when receiving a positioning completion notification of the robot arm 40, the controller 158 moves the board recognition imager 154b to the corresponding position from tool confirmation position information transmitted together with the notification or tool confirmation position information defined in advance. Then, the controller 158 images the marks 60a of the tool 60 with the board recognition imager 154b to acquire the position of the tool 60.

The controller 158 recognizes the object transported in the movable range of the mounting heads 154a and controls the mounting heads 154a to receive the object from the robot arm 40 based on the recognition result. Furthermore, the controller 158 recognizes the type of object transported in the movable range of the mounting heads 154a.

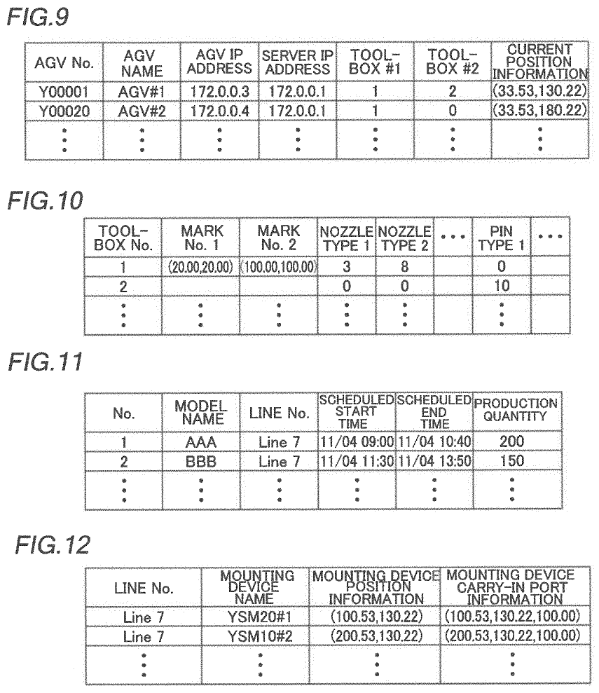

When the component mounting device 15 requests the tool 60, the server 20 uses the information shown in FIGS. 9 to 12 to perform a process such that the autonomous mobile cart 30 transports the tool 60 to the component mounting device 15.

As shown in FIG. 9, the server 20 manages the serial number of the autonomous mobile cart 30 (AGV), the name of the autonomous mobile cart 30 (AGV), the IP address of the autonomous mobile cart 30 (AGV), the IP address of the corresponding server 20, information on the tool 60 placed on the placement portion 50 (toolbox), and current position information of the autonomous mobile cart 30 (AGV). Furthermore, the server 20 manages tool holding information (type, height, and arrangement information) of the autonomous mobile cart 30 (AGV).

As shown in FIG. 10, the server 20 manages information on the tool 60 corresponding to the toolbox number of the tool 60 placed on the placement portion 50 (toolbox). The information on the tool 60 includes position information of the plurality of marks 60a of the tool 60, the type information of the nozzle 62a, and the type information of the backup pin 61a.

The server 20 manages production plan information, as shown in FIG. 11. The production plan information includes a model name, a line number, a scheduled production start time, a scheduled production end time, a production quantity. Based on the production plan, the server 20 predicts the device that requires transportation of the tool 60 and manages ensuring the autonomous mobile cart 30 in advance such that the autonomous mobile cart 30 can be directed.

As shown in FIG. 12, the server 20 manages position information of the plurality of component mounting devices 15. The position information of the component mounting devices 15 includes line information, component mounting device information (mounting device name), device position information, and position information of the carry-in ports 15b of the component mounting devices 15.

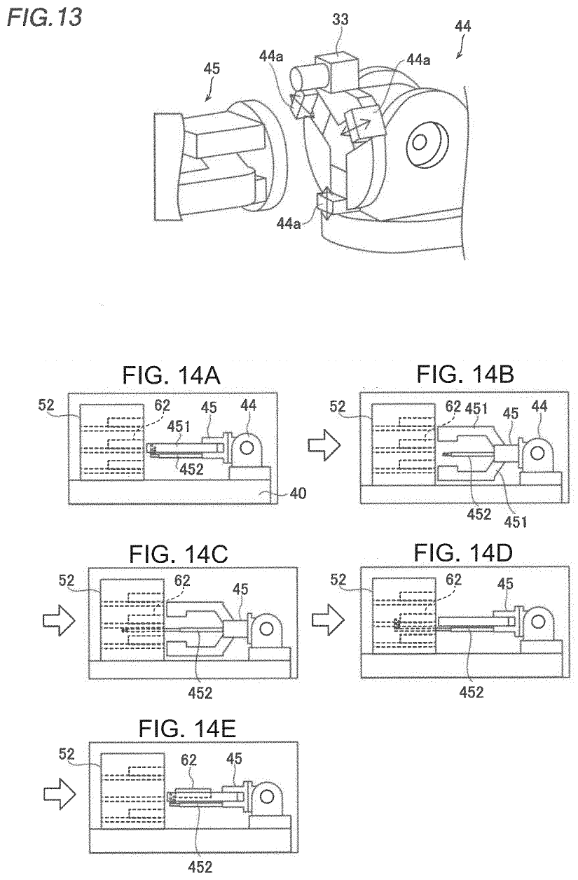

As shown in FIG. 13, the hand holder 44 of the robot arm 40 includes a plurality of claws 44a. The plurality of claws 44a move inward to fix the hand 45. The claws 44a is electrically driven under the control of the controller 32.

As shown in FIGS. 14A-14E, the robot arm 40 holds and transports the nozzle stocker 62 on the nozzle placement portion 52 provided on the autonomous mobile cart 30. As shown in FIG. 14A, the robot arm 40 moves the hand 45 to the side of the nozzle stocker 62 to be transported. Then, as shown in FIG. 14B, the hand 45 rotates such that a pair of grips 451 of the hand 45 are aligned in the vertical direction. That is, the hand 45 rotates such that a convex portion of the tip end of an expansion and contraction portion 452 protrudes in the horizontal direction. The hand 45 is rotatable with respect to the hand holder 44. The pair of grips 451 of the hand 45 are openable and closable. The expansion and contraction portion 452 of the hand 45 is expandable and contractible. When the hand 45 is held by the hand holder 44 of the robot arm 40, a terminal of the hand 45 is connected and electric power is supplied from the robot arm 40 to the hand 45. The hand 45 is driven by the electric power supplied from the robot arm 40.

As shown in FIG. 14C, the hand 45 expands the expansion and contraction portion 452. Then, as shown in FIG. 14D, the hand 45 rotates such that the pair of grips 451 of the hand 45 are aligned in the horizontal direction. That is, the hand 45 rotates such that the convex portion of the tip end of the expansion and contraction portion 452 protrudes upward. Thus, the convex portion of the tip end of the expansion and contraction portion 452 is hooked onto the nozzle stocker 62 to be transported. As shown in FIG. 14E, the hand 45 contracts the expansion and contraction portion 452. Thus, the nozzle stocker 62 is drawn to the pair of grips 451. Consequently, the nozzle stocker 62 is held by the hand 45. While the nozzle stocker 62 is held by the hand 45, a switching portion of the nozzle stocker 62 can be operated by the expansion and contraction portion 452. Thus, the nozzle stocker 62 held by the hand 45 can be switched between a state of holding the nozzle 62a and a state of releasing holding of the nozzle 62a.

As shown in FIG. 15, the robot arm 40 holds and transports the backup pin stocker 61 on the backup pin placement portion 51 provided on the autonomous mobile cart 30. The robot arm 40 grips the backup pin stocker 61 to be transported from below with the hand 45 removed. Specifically, the robot arm 40 holds the backup pin stocker 61 with the hand holder 44. On a lower portion of the backup pin stocker 61, a gripped portion having the same shape as the hand 45 is provided.

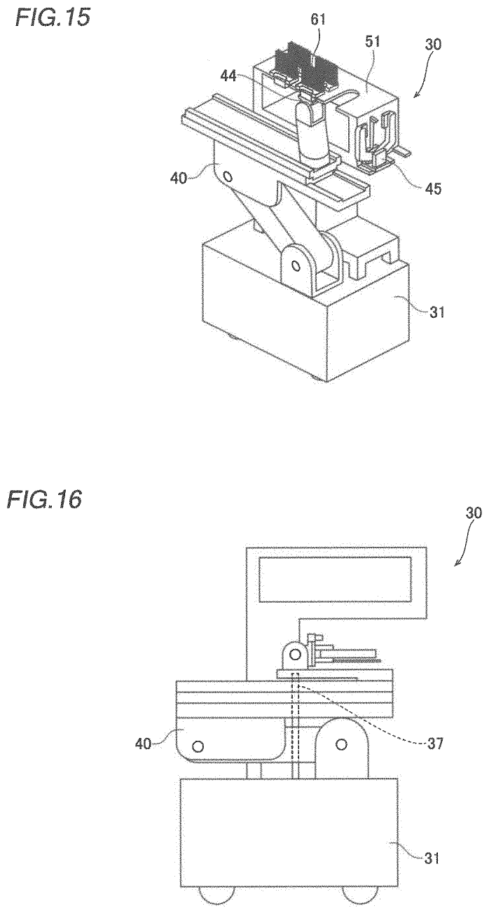

As shown in FIG. 16, the movement restrictor 37 of the autonomous mobile cart 30 fixes the robot arm 40 to the autonomous mobile cart main body 31 such that the robot arm 40 does not move when the autonomous mobile cart main body 31 is traveling. Specifically, the movement restrictor 37 extends a rod-shaped movement restricting member upward from the autonomous mobile cart main body 31, and the movement restricting member passes through a through-hole provided in each portion of the robot arm 40 such that the robot arm 40 is fixed to the autonomous mobile cart main body 31.

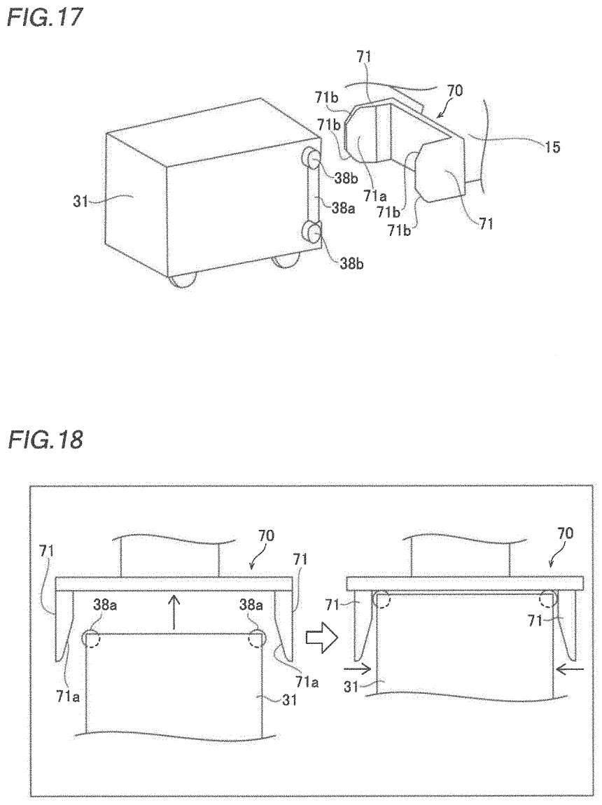

As shown in FIGS. 17 and 18, the autonomous mobile cart main body 31 is connected to the component mounting device 15. The component mounting device 15 includes a connecting portion 70 that connects and fixes the autonomous mobile cart main body 31 on the passage side extending in parallel to the mounting line 10. Then, the robot arm 40 transports the object used in the component mounting device 15 into the component mounting device 15 while the autonomous mobile cart main body 31 is connected to the connecting portion 70 of the component mounting device 15.

The autonomous mobile cart main body 31 includes a pair of rollers 38a that can rotate about a rotation axis along the vertical direction, and a plurality of rollers 38b that can rotate about a rotation axis along the horizontal direction. One roller 38a is provided on each of the right and left sides of the autonomous mobile cart main body 31. Two rollers 38b are provided on each of the left and right sides of the autonomous mobile cart main body 31. Pairs of right and left rollers 38b are arranged at intervals in the vertical direction so as to interpose the rollers 38a therebetween.

The connecting portion 70 includes a pair of clamps 71 arranged along the horizontal direction. Each of the pair of clamps 71 includes a taper 71a and tapers 71b. As shown in FIG. 18, the tapers 71a are formed such that a distance therebetween reduces toward the component mounting device 15 in a plan view. Thus, the autonomous mobile cart main body 31 is guided between the pair of clamps 71 along the tapers 71a. At this time, the rollers 38a of the autonomous mobile cart main body 31 rotate when contacting the clamps 71. As shown in FIG. 17, a pair of tapers 71b are arranged one above the other on each of the pair of clamps 71. The tapers 71b are formed such that distances therebetween increase toward the component mounting device 15. Thus, the autonomous mobile cart main body 31 is guided to ride on the clamps 71. At this time, the rollers 38b of the autonomous mobile cart main body 31 rotate when contacting the clamps 71. The clamps 71 of the connecting portion 70 reduce a distance therebetween to clamp the autonomous mobile cart main body 31 when the autonomous mobile cart main body 31 is arranged between the clamps 71.

As shown in FIGS. 19A-19C, the robot arm 40 transports the object used in the component mounting device 15 into the component mounting device 15 through the opening of the component mounting device 15. Specifically, the robot arm 40 transports the tool 60 used by the component mounting device 15 into and out of the component mounting device 15 through the carry-in port 15b. The opening (carry-in port 15b) of the component mounting device 15 is designed such that the robot arm 40 can be inserted from the front of the component mounting device 15 toward the conveyors 152 (board conveyance portions) of the component mounting device 15 that convey the board S. As shown in FIG. 5, the opening (carry-in port 15b) of the component mounting device 15 is provided in the vicinity of one side end in the conveyance direction (X direction) of the board S. The robot arm 40 transports the tool 60 to a height substantially the same as the height of the board S through the carry-in port 15b.

The controller 32 controls driving of the robot arm 40 such that the robot arm 40 transports the object used in the component mounting device 15 into and out of the component mounting device 15 within the movable range of the mounting heads 154a in the component mounting device 15 in a plan view. Specifically, the controller 32 controls driving of the robot arm 40 such that the robot arm 40 delivers and receives the object used in the component mounting device 15 to and from the mounting heads 154a in the component mounting device 15.

As shown in FIGS. 19A-19C, at the carry-in port 15b, a cover 15d and a drive 15e that moves the cover 15d are provided. The cover 15d is switched between an open state in which the carry-in port 15b is opened and a closed state in which the carry-in port 15b is closed by the drive 15e.

As shown in FIG. 19A, the autonomous mobile cart 30 arrives in front of the component mounting device 15. At this time, the controller 32 recognizes the position of the opening (carry-in port 15b) through which the robot arm 40 is inserted into the component mounting device 15, and moves the autonomous mobile cart main body 31 to the position of the carry-in port 15b. Then, as shown in FIG. 19B, the cover 15d is opened. Thus, the carry-in port 15b is opened. Then, as shown in FIG. 19C, the robot arm 40 is inserted into the component mounting device 15 through the opened carry-in port 15b. At this time, the height of the tool 60 (backup pin stocker 61) to be transported is adjusted by the vertical movement portion 41 of the robot arm 40, and the horizontal movement section 42 is extended such that the tool 60 is inserted into the component mounting device 15. Furthermore, while the tool 60 is inserted into the component mounting device 15, the horizontal rotation portion 43 is rotated such that the position of the tool 60 is adjusted.

The controller 32 controls driving of the robot arm 40 such that the robot arm 40 transports the object used in the component mounting device 15 to a position designated by the component mounting device 15 or a preset position of the component mounting device 15. The component mounting device 15 retracts the mounting heads 154a such that the mounting heads 154a do not interfere with the robot arm 40 when the robot arm 40 is inserted.

As shown in FIGS. 20A-20C, the robot arm 40 removes the component supply cart 153b from the component mounting device 15 and transports the object used in the component mounting device 15 into the component mounting device 15 through an opening created by removing the component supply cart 153b from the component mounting device 15.

As shown in FIG. 20A, the robot arm 40 grips the component supply cart 153b with the hand holder 44. A gripped portion having the same shape as the hand 45 is provided on the outside of the component supply cart 153b. As shown in FIG. 20B, while the robot arm 40 grips and connects the component supply cart 153b, the autonomous mobile cart 30 moves to remove the component supply cart 153b from the component mounting device 15.

After that, the autonomous mobile cart 30 moves the component supply cart 153b to a position at which the component supply cart 153b does not interfere. Then, the robot arm 40 releases the grip of the component supply cart 153b by the hand holder 44. As shown in FIG. 20C, the autonomous mobile cart 30 moves to a position at which the parts supply cart 153b is removed. The robot arm 40 transports the object used in the component mounting device 15 into the component mounting device 15 through the opening created by removing the component supply cart 153b from the component mounting device 15.

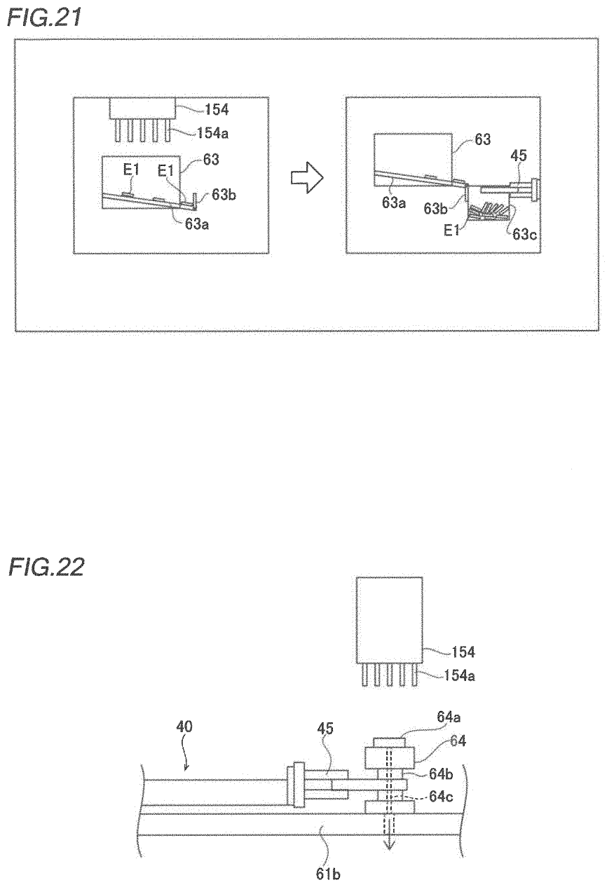

As shown in FIG. 21, the robot arm 40 collects the waste E1 accumulated in the waste box 63. The waste E1 includes a defective component E, a component E of which the mounting has failed, etc. The waste E1 is discarded in the waste box 63 by the mounting heads 154a. The waste box 63 includes a slope 63a and a stopper 63b. Furthermore, the waste box 63 includes a collection container 63c.

The waste E1 discarded by the mounting heads 154a is stored in the waste box 63. The robot arm 40 brings the collection container 63c into contact with the stopper 63b and collects the waste E1 from the waste box 63 to the collection container 63c via the slope 63a. Furthermore, the robot arm 40 collects the waste E1 in the collection container 63c to the waste storage 53 of the autonomous mobile cart 30. At this time, the lower end of the slope 63a is covered with the stopper 63b, and run-off of the waste E1 is significantly reduced or prevented.

As shown in FIG. 22, the robot arm 40 transports a calibration jig 64 used to calibrate the component mounting device 15 into the component mounting device 15. The calibration jig 64 includes a jig component 64a and a base 64b. The jig component 64a of the calibration jig 64 is suctioned by the mounting heads 154a of the component mounting device 15 and is placed on the base 64b. Then, the position of the jig component 64a placed on the base 64b is imaged by the board recognition imager 154b, and movement of the mounting heads 154a is calibrated (adjusted) based on the imaging result. The base 64b includes an air passage 64c for supplying a negative pressure. The negative pressure is supplied to the air passage 64c via a plate 61b on which the backup pin 61a is placed. Thus, the jig component 64a can be suctioned and fixed to the base 64b by the negative pressure, and thus the displacement of the jig component 64a placed on the base 64b can be significantly reduced or prevented. When the calibration jig 64 is transported by the robot arm 40, claws of the hand 45 cover the top of the jig component 64a to significantly reduce or prevent fall of the jig component 64a from the base 64b.

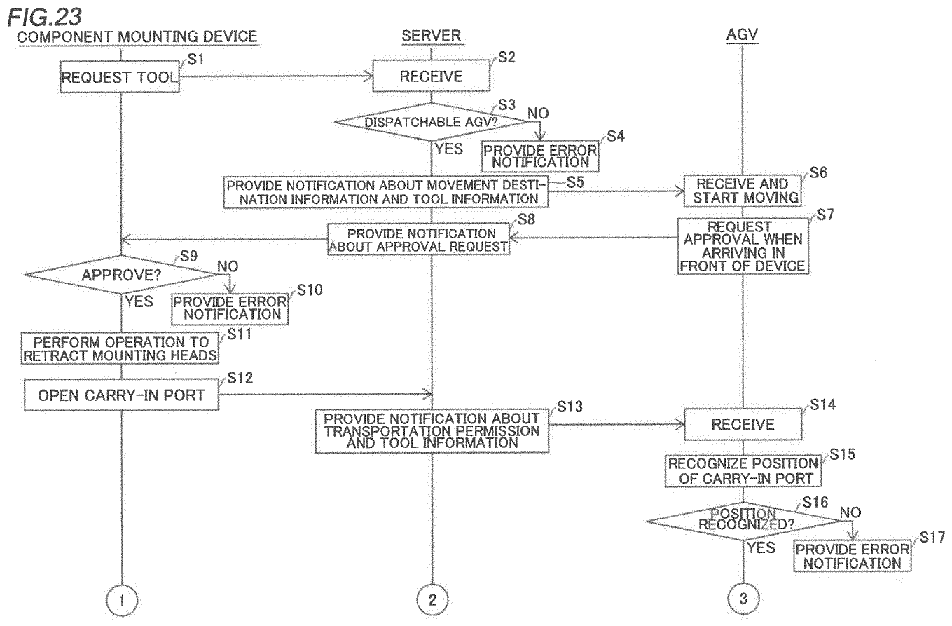

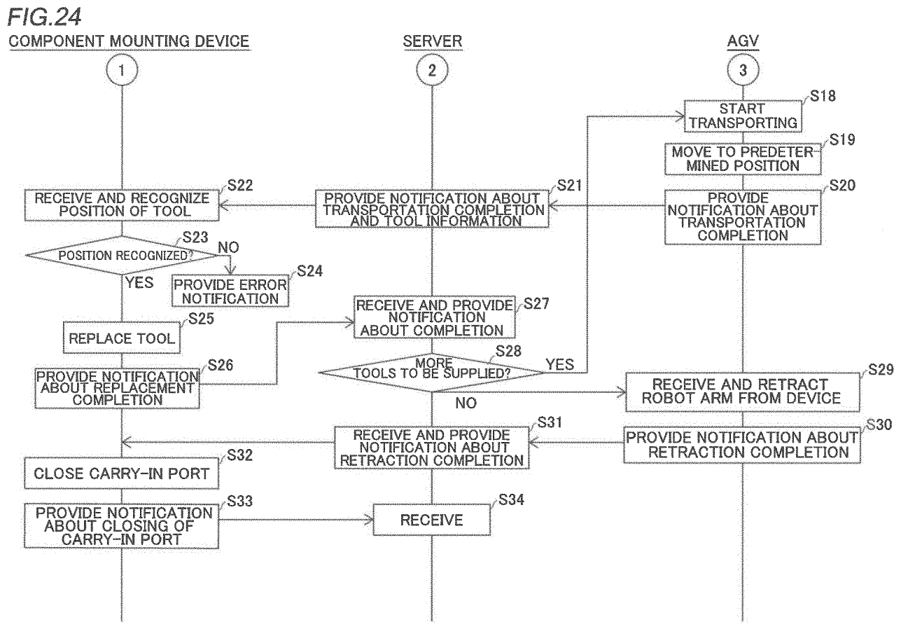

As shown in FIGS. 23 and 24, the server 20 controls a supply of the tool 60 to the component mounting device 15 by the autonomous mobile cart 30. In other words, the server 20 receives information on a demanded object from the component mounting device 15 and transmits, to the corresponding autonomous mobile cart 30, an instruction to transport the object to the component mounting device 15.

In step S1 of FIG. 23, a request for the tool 60 is transmitted from the component mounting device 15 to the server 20. In step S2, the server 20 receives the request for the tool 60. In step S3, the server 20 determines whether or not the autonomous mobile cart 30 (AGV) holding the requested tool 60 can be dispatched. When the autonomous mobile cart 30 holding the requested tool 60 cannot be dispatched because it is dispatched to another device, the server 20 notifies the component mounting device 15 of an error in step S4.

When the autonomous mobile cart 30 holding the requested tool 60 can be dispatched, the server 20 notifies the corresponding autonomous mobile cart 30 of movement destination information (information on the component mounting device 15) and information on the tool 60 in step S5. In step S6, the autonomous mobile cart 30 receives the movement destination information and the tool information, and starts moving to the designated component mounting device 15.

In step S7, when the autonomous mobile cart 30 arrives in front of the designated component mounting device 15, it requests the server 20 to approve transportation of the tool 60 to the component mounting device 15. In step S8, the server 20 notifies the component mounting device 15 of the approval request received from the autonomous mobile cart 30.

In step S9, the component mounting device 15 determines whether or not to approve transportation of the tool 60. When approval is not possible because the carry-in port 15b cannot be opened, for example, the component mounting device 15 notifies the autonomous mobile cart 30 of an error via the server 20 in step S10. When approval is possible, the component mounting device 15 performs an operation to retract the mounting heads 154a in step S11. In step S12, the component mounting device 15 opens the carry-in port 15b. Then, the component mounting device 15 notifies the server 20 that the carry-in port 15b has been opened.

In step S13, the server 20 notifies the autonomous mobile cart 30 of permission to transport the tool 60 into the component mounting device 15 and the information on the tool 60. In step S14, the autonomous mobile cart 30 receives the transportation permission and the tool information. In step S15, the autonomous mobile cart 30 recognizes the position of the carry-in port 15b.

In step S16, the autonomous mobile cart 30 determines whether or not the position of the carry-in port 15b has been recognized. When the position of the carry-in port 15b cannot be recognized, the autonomous mobile cart 30 notifies the server 20 of an error in step S17.

When the position of the carry-in port 15b can be recognized, the autonomous mobile cart 30 starts transporting the tool 60 into the component mounting device 15 with the robot arm 40 in step S18 of FIG. 24. In step S19, the autonomous mobile cart 30 moves the robot arm 40 to a predetermined position. In step S20, the autonomous mobile cart 30 notifies the server 20 that transportation of the tool 60 into the component mounting device 15 by the robot arm 40 has been completed.

In step S21, the server 20 notifies the component mounting device 15 of the transportation completion received from the autonomous mobile cart 30 and the information on the tool 60 transported into the component mounting device 15. In step S22, the component mounting device 15 receives the notification from the server 20 and recognizes the position of the tool 60 based on the imaging result of the board recognition imager 154b.

In step S23, the component mounting device 15 determines whether or not the position of the tool 60 has been recognized. When the position of the tool 60 cannot be recognized, the component mounting device 15 notifies the server 20 of an error in step S24. When the position of the tool 60 can be recognized, the component mounting device 15 receives the tool 60 transported by the robot arm 40 and replaces the old tool 60 with the transported tool 60 with the mounting heads 154a in step S25. In step S26, the component mounting device 15 notifies the server 20 of the completion of replacement of the tool 60.

In step S27, the server 20 receives the notification of the replacement completion from the component mounting device 15 and notifies the autonomous mobile cart 30 of the replacement completion. In step S28, the server 20 determines whether or not there are more tools 60 to be supplied. When there are more tools 60 to be supplied, the server 20 notifies the autonomous mobile cart 30 and returns to step S18. When there are no tools 60 to be supplied, the server 20 notifies the autonomous mobile cart 30 that the supply of the tools 60 has been completed.

In step S29, the autonomous mobile cart 30 receives the completion notification from the server and retracts the robot arm 40 from the component mounting device 15. In step S30, the autonomous mobile cart 30 notifies the server 20 of the completion of retraction of the robot arm 40.

In step S31, the server 20 receives the retraction completion notification from the autonomous mobile cart 30 and notifies the component mounting device 15 of the retraction completion. In step S32, the component mounting device 15 closes the carry-in port 15b. In step S33, the component mounting device 15 transmits the closing of the carry-in port 15b to the server 20. In step S34, the server 20 receives the closing of the carry-in port 15b and terminates the process in which the autonomous mobile cart 30 supplies the tool 60 to the component mounting device 15.

### Advantageous Effects of this Embodiment

According to this embodiment, the following advantageous effects are achieved.

According to this embodiment, as described above, the controller 32 is configured or programmed to control driving of the robot arm 40 such that the robot arm 40 transports the object used in the component mounting device 15 into and out of the component mounting device 15 within the movable range of the mounting heads 154a in the component mounting device 15 in the plan view. Accordingly, the robot arm 40 can transport the object used in the component mounting device 15 into and out of the component mounting device 15, and thus the operator does not need to transport the object into and out of the component mounting device 15. Consequently, it is possible to reduce the work burden on the operator when the object used in the component mounting device 15 is transported into and out of the component mounting device 15. Moreover, unlike a case in which the operator transports the object into and out of the component mounting device 15, it is not necessary to stop the operation of the component mounting device 15 completely. Thus, it is possible to significantly reduce or prevent a decrease in the efficiency (productivity) of board manufacturing by the component mounting device 15. Furthermore, the object can be transported into and out of the component mounting device 15 by the robot arm 40 when necessary in the component mounting device 15, and thus it is not necessary to provide a storage space for storing the object in the component mounting device 15 in case the object used in the component mounting device 15 is required. Thus, the component mounting device 15 can be downsized.

According to this embodiment, as described above, the controller 32 is configured or programmed to control driving of the robot arm 40 such that the robot arm 40 delivers and receives the object used in the component mounting device 15 to and from the mounting heads 154a in the component mounting device 15. Accordingly, the mounting heads 154a that work on the board S can be used to deliver and receive the object to and from the robot arm 40, and thus it is not necessary to provide a dedicated member for delivering and receiving the object to and from the robot arm 40. Thus, it is possible to significantly reduce or prevent an increase in the number of components of the component mounting device 15 and to significantly reduce or prevent the complexity of the device structure.

According to this embodiment, as described above, the component mounting device 15 is configured to recognize the object transported into the movable range of the mounting heads 154a and receive the object from the robot arm 40 with the mounting heads 154a based on the recognition result. Accordingly, the position of the transported object can be accurately recognized, and the transported object can be reliably received by the mounting heads 154a.

According to this embodiment, as described above, the component mounting device 15 is configured to recognize the type of object transported into the movable range of the mounting heads 154a. Accordingly, the object can be received by the mounting heads 154a in a suitable manner according to the type of transported object.

According to this embodiment, as described above, the component mounting device 15 is configured to image the object transported into the movable range of the mounting heads 154a with the board recognition imager 154b and recognize the object based on the imaging result. Accordingly, the board recognizing imager 154b that recognizes the board S can be used to image and recognize the transported object, and thus it is not necessary to provide a dedicated member for recognizing the transported object. Thus, it is possible to significantly reduce or prevent an increase in the number of components of the component mounting device 15 and to significantly reduce or prevent the complexity of the device structure.

According to this embodiment, as described above, the controller 32 is configured or programmed to control driving of the robot arm 40 such that the robot arm 40 delivers and receives the object used in the component mounting device 15 to and from the mounting heads 154a of the component mounting device 15. Accordingly, the robot arm 40 can deliver and receive the object used in the component mounting device 15 to and from the mounting heads 154a of the component mounting device 15, and thus it is possible to reduce the work burden on the operator when the object used in the component mounting device 15 is transported into and out of the component mounting device 15.

According to this embodiment, as described above, the server 20 is configured to receive the information on a demanded object from the component mounting device 15 and transmit, to the corresponding autonomous mobile cart 30, the instruction to transport the object to the component mounting device 15. Accordingly, the server 20 can collectively manage the objects to be transported to the plurality of component mounting devices 15, and thus the objects can be efficiently transported to the plurality of component mounting devices 15.

According to this embodiment, as described above, the controller 32 is configured or programmed to recognize the position of the opening through which the robot arm 40 is inserted into the component mounting device 15 and move the autonomous mobile cart to the position of the opening. Accordingly, the robot arm 40 can be easily inserted into the opening of the component mounting device 15 and easily transport the object into and out of the component mounting device 15.

According to this embodiment, as described above, the controller 32 is configured or programmed to control driving of the robot arm 40 such that the robot arm 40 transports the object used in the component mounting device 15 to the position designated by the component mounting device 15 or the preset position of the component mounting device 15. Accordingly, the robot arm 40 can transport the object used in the component mounting device 15 to the predetermined position, and thus the transported object can be easily delivered and received by a predetermined operation of the component mounting device 15.

According to this embodiment, as described above, the component mounting device 15 is configured to retract the mounting heads 154a such that the mounting heads 154a do not interfere with the robot arm 40 when the robot arm 40 is inserted. Accordingly, it is possible to significantly reduce or prevent interference between the robot arm 40 and the mounting heads 154a of the component mounting device 15 while the robot arm 40 is transporting the object, and thus it is possible to significantly reduce or prevent fall of the object from the robot arm 40.

According to this embodiment, as described above, the object used in the component mounting device 15 includes the backup pin 61a configured to support the board S, the nozzle 62a configured to suction the component E, the waste box 63 in which the component E is discarded, and the calibration jig 64 used to calibrate the component mounting device 15. Accordingly, it is possible to reduce the work burden on the operator when the backup pin 61a, the nozzle 62a, the waste box 63, and the calibration jig 64 are transported to the component mounting device 15.

### MODIFIED EXAMPLES

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which the object used in the component mounting device corresponding to a board work device includes the backup pin that supports the board, the nozzle that suctions the component, the waste box in which the component is discarded, and the calibration jig used to calibrate the board work device has been shown in the aforementioned embodiment, the present disclosure is not restricted to this. In the present disclosure, the object used in the board work device is simply required to include at least one of the backup pin that supports the board, the nozzle that suctions the component, the waste box in which the component is discarded, or the calibration jig used to calibrate the board work device.

While the example in which the controller that controls driving of the robot arm is provided in the autonomous mobile cart main body has been shown in the aforementioned embodiment, the present disclosure is not restricted to this. In the present disclosure, the controller that controls driving of the robot arm may be provided in the robot arm.

While the example in which the camera corresponding to a detector that detects the position of the opening of the board work device is provided on the autonomous mobile cart main body has been shown in the aforementioned embodiment, the present disclosure is not restricted to this. In the present disclosure, the detector that detects the position of the opening of the board work device may be provided on the robot arm.

While the example in which the plurality of mounting lines are provided in the board manufacturing system has been shown in the aforementioned embodiment, the present disclosure is not restricted to this. In the present disclosure, one mounting line may be provided in the board manufacturing system.

While the example in which the hand holder fixes the hand with the plurality of claws has been shown in the aforementioned embodiment, the present disclosure is not restricted to this. In the present disclosure, the hand holder may fix the hand with a mechanism that moves a ball.

While the example in which the autonomous mobile cart transports the object to the component mounting device corresponding to the board work device by performing communication via the server has been shown in the aforementioned embodiment, the present disclosure is not restricted to this. In the present disclosure, the autonomous mobile cart may transport the object to the board work device by directly communicating with the board work device.

While the control process is described, using the flow described in a manner driven by a flow in which processes are performed in order along a process flow for the convenience of illustration in the aforementioned embodiment, the present disclosure is not restricted to this. In the present disclosure, the control process may be performed in an event-driven manner in which processes are performed on an event basis. In this case, the control process may be performed in a complete event-driven manner or in a combination of an event-driven manner and a manner driven by a flow.

What is claimed is:

1. A board manufacturing system comprising:
a mounting line including a plurality of board work devices, the plurality of board work devices including a component mounting device configured to mount a component on a board;
an autonomous mobile cart configured to transport an object used in the board work devices of the mounting line;
a robot arm on the autonomous mobile cart and configured to transport the object used in the board work devices to the board work devices; and
a controller in the autonomous mobile cart or the robot arm and configured or programmed to control driving of the robot arm; wherein
the board work devices include a working unit configured to work on the board; and
the controller is configured or programmed to control the driving of the robot arm such that the robot arm transports the object used in the board work devices into and out of the board work devices within a movable range of the working unit in the board work devices in a plan view; and
the controller is configured or programmed to control the driving of the robot arm such that the robot arm delivers and receives the object used in the board work devices to and from the working unit in the board work devices.

2. (canceled)

3. The board manufacturing system according to claim 1, wherein the board work devices are configured to recognize the object transported into the movable range of the working unit and receive the object from the robot arm with the working unit based on a recognition result.

4. The board manufacturing system according to claim 3, wherein the board work devices are configured to recognize a type of the object transported into the movable range of the working unit.

5. The board manufacturing system according to claim 3, wherein the board work devices include a camera configured to recognize the board to be worked on, and are configured to image the object transported into the movable range of the working unit with the camera and recognize the object based on an imaging result.

6. The board manufacturing system according to claim 1, wherein the controller is configured or programmed to control the driving of the robot arm such that the robot arm delivers and receives the object used in the component mounting device to and from a mounting head corresponding to the working unit of the component mounting device.

7. The board manufacturing system according to claim 1, further comprising:
a server configured to communicate with the autonomous mobile cart and the plurality of board work devices; wherein
the server is configured to receive information on a demanded object from the board work devices and transmit, to the corresponding autonomous mobile cart, an instruction to transport the object to the board work devices.

8. The board manufacturing system according to claim 1, wherein the controller is configured or programmed to recognize a position of an opening through which the robot arm is inserted into the board work devices and move the autonomous mobile cart to the position of the opening.

9. The board manufacturing system according to claim 1, wherein the controller is configured or programmed to control the driving of the robot arm such that the robot arm transports the object used in the board work devices to positions designated by the board work devices or preset positions of the board work devices.

10. The board manufacturing system according to claim 1, wherein the board work devices are configured to retract the working unit such that the working unit does not interfere with the robot arm when the robot arm is inserted.

11. The board manufacturing system according to claim 1, wherein the object used in the board work devices includes at least one of a backup pin configured to support the board, a nozzle configured to suction the component, a waste box in which the component is discarded, or a calibration jig used to calibrate the board work devices.

12. An autonomous mobile cart comprising:
an autonomous mobile cart main body configured to transport an object used in board work devices of a mounting line including a plurality of the board work devices, the plurality of board work devices including a component mounting device configured to mount a component on a board;
a robot arm on the autonomous mobile cart main body and configured to transport the object used in the board work devices to the board work devices; and
a controller in the autonomous mobile cart main body or the robot arm and configured or programmed to control driving of the robot arm; wherein
the controller is configured or programmed to control the driving of the robot arm such that the robot arm transports the object used in the board work devices into and out of the board work devices within a movable range of a working unit configured to work on the board in the board work devices in a plan view; and
the controller is configured or programmed to control the driving of the robot arm such that the robot arm delivers and receives the object used in the board work devices to and from the working unit in the board work devices.

13. A board manufacturing method in a mounting line including a plurality of board work devices, the plurality of board work devices including a component mounting device configured to mount a component on a board, the board manufacturing method comprising:
transporting an object used in the board work devices of the mounting line by an autonomous mobile cart;
driving a robot arm such that the robot arm transports the object used in the board work devices into and out of the board work devices within a movable range of a working unit configured to work on the board in the board work devices in a plan view; and
driving the robot arm such that the robot arm delivers and receives the object used in the board work devices to and from the working unit in the board work devices.

14. The board manufacturing system according to claim 4, wherein the board work devices include a camera configured to recognize the board to be worked on, and are configured to image the object transported into the movable range of the working unit with the camera and recognize the object based on an imaging result.

15. The board manufacturing system according to claim 3, wherein the controller is configured or programmed to control the driving of the robot arm such that the robot arm delivers and receives the object used in the component mounting device to and from a mounting head corresponding to the working unit of the component mounting device.

16. The board manufacturing system according to claim 3, further comprising:
a server configured to communicate with the autonomous mobile cart and the plurality of board work devices; wherein
the server is configured to receive information on a demanded object from the board work devices and transmit, to the corresponding autonomous mobile cart, an instruction to transport the object to the board work devices.

17. The board manufacturing system according to claim 3, wherein the controller is configured or programmed to recognize a position of an opening through which the robot arm is inserted into the board work devices and move the autonomous mobile cart to the position of the opening.

18. The board manufacturing system according to claim 3, wherein the controller is configured or programmed to control the driving of the robot arm such that the robot arm transports the object used in the board work devices to positions designated by the board work devices or preset positions of the board work devices.

19. The board manufacturing system according to claim 3, wherein the board work devices are configured to retract the working unit such that the working unit does not interfere with the robot arm when the robot arm is inserted.

20. The board manufacturing system according to claim 3, wherein the object used in the board work devices includes at least one of a backup pin configured to support the board, a nozzle configured to suction the component, a waste box in which the component is discarded, or a calibration jig used to calibrate the board work devices.
